(19) United States
(12) Patent Application Publication
(10) Pub. No.: US 2026/0107817 A1
(43) Pub. Date: Apr. 16, 2026

(54) SEMICONDUCTOR PACKAGE

(71) Applicant: Samsung Electronics Co., Ltd., Suwon-si (KR)

(72) Inventors: Hyunho Chu, Suwon-si (KR); Sanghyeon Lee, Suwon-si (KR)

(21) Appl. No.: 19/315,946

(22) Filed: Sep. 2, 2025

(30) Foreign Application Priority Data
Oct. 14, 2024 (KR) 10-2024-0139282

(51) Int. Cl. H01L 23/00; H01L 23/31; H01L 25/00; H01L 25/065; H01L 25/18; H10B 80/00; H10D 80/30

(52) U.S. Cl. CPC H10W 72/90; H10W 90/00; H10B 80/00; H10D 80/30; H10W 72/07553; H10W 72/531; H10W 72/865; H10W 72/884; H10W 72/9415; H10W 72/9445; H10W 74/117; H10W 90/20; H10W 90/24; H10W 90/732; H10W 90/734; H10W 90/754

(57) ABSTRACT

An embodiment provides a semiconductor package including a package substrate including substrate pads, and a chip stack including a plurality of semiconductor chips stacked on the package substrate, wherein the plurality of semiconductor chips include first and second semiconductor chips having the same size and shape device region, the first and second semiconductor chips include first and second chip pad regions protruding from different regions of a first side of the device region, respectively, and each chip pad being connected to a substrate pad by a wire, and the first and second semiconductor chips are stacked such that the first and second chip pad regions face in the same horizontal direction and do not overlap each other in a stacking direction.

### CROSS-REFERENCE TO RELATED APPLICATION(S)

This U.S. non-provisional application claims benefit of priority to Korean Patent Application No. 10-2024-0139282 filed on Oct. 14, 2024 in the Korean Intellectual Property Office, the disclosure of which is incorporated herein by reference in its entirety.

### BACKGROUND

The present inventive concept relates to a semiconductor package.

With the development of the electronics industry, demand for high functionality, high speed, and miniaturization of electronic components is increasing. In accordance with this trend, a semiconductor packaging technology for embedding a plurality of semiconductor chips in a single package is being developed. A method for minimizing an increase in package size due to arrangement of the plurality of semiconductor chips is required.

### SUMMARY

An aspect of the present inventive concept is to provide a semiconductor package that is advantageous in terms of lightness, thinness, and miniaturization while ensuring reliability.

According to an aspect of the present inventive concept, a semiconductor package includes a package substrate having a first side and a second side opposing the first side, the package substrate including first substrate pads adjacent to the first side and second substrate pads adjacent to the second side; and a chip stack including a plurality of semiconductor chips disposed between the first substrate pads and the second substrate pads on the package substrate, wherein the plurality of semiconductor chips include first to fourth semiconductor chips each having a same device region, wherein each of the first and third semiconductor chips includes a corresponding first chip pad region protruding from a first region of a first side of the device region of the first and third semiconductor chips, each of the second and fourth semiconductor chips includes a corresponding second chip pad region protruding from a second region of a first side of the device region of the second and fourth semiconductor ships, and chip pads are disposed in each of the first and second chip pad regions, the plurality of chip pads include a first plurality of chip pads in a first chip pad region of the first and third semiconductor chips, and a second plurality of chip pads in a second chip pad region of the second and fourth semiconductor chips, the first and second semiconductor chips are stacked such that the first chip pad region of the first semiconductor chip and the second chip pad region of the second semiconductor chip face the first side of the package substrate and do not overlap each other in a stacking direction, and the first plurality of chip pads of the first semiconductor chip and the second plurality of chip pads of the second semiconductor chip are electrically connected to the first substrate pads, and the third and fourth semiconductor chips are stacked such that the first chip pad region of the third semiconductor chip and the second chip pad region of the fourth semiconductor chip face the second side of the package substrate and do not overlap each other in the stacking direction, and the first plurality of chip pads of the third semiconductor chip and the second plurality of chip pads of the fourth semiconductor chip are electrically connected to the second substrate pads.

According to an aspect of the present inventive concept, a semiconductor package includes a package substrate having a first side and a second side opposing the first side, the package substrate including first substrate pads adjacent to the first side and second substrate pads adjacent to the second side; and a chip stack including a plurality of sub-stacks disposed between the first substrate pads and the second substrate pads on the package substrate, and each sub-stack of the plurality of sub-stacks having a corresponding first semiconductor chip and a second semiconductor chip, wherein each of the first semi-conductor chips and the second semiconductor chips include a device region, the first semiconductor chips include corresponding first chip pad regions protruding from a first region of a first side of the device region of the first semiconductor chips, the second semiconductor chips include corresponding second chip pad regions protruding from a second region of a first side of the device region of the second semiconductor chips, and a plurality of chip pads are disposed in the first chip pad region and in the second chip pad region, the plurality of sub-stacks include a first sub-stack and a second sub-stack, sequentially stacked on the package substrate, in the first sub-stack, the first and second semiconductor chips are stacked such that the first and second chip pad regions face the first side of the package substrate and do not overlap each other in a stacking direction, and each chip pad of the plurality of chip pads in the first chip pad region and the second chip pad region of the first sub-stack is connected to a corresponding substrate pad of the first substrate pads by a corresponding wire, in the second sub-stack, the first and second semiconductor chips are stacked such that the first and second chip pad regions face the second side of the package substrate and do not overlap each other in the stacking direction, and each chip pad of the plurality of chip pads in the first chip pad region and the second chip pad region of the second sub-stack is connected to a corresponding substrate pad of the second substrate pads by a corresponding wire.

According to an aspect of the present inventive concept, a semiconductor package includes a package substrate including substrate pads; a chip stack including a plurality of semiconductor chips stacked on the package substrate; and a molding film surrounding the chip stack on the package substrate, wherein the plurality of semiconductor chips include first and second semiconductor chips each having a device region having the same size and the same shape, the first and second semiconductor chips include first and second chip pad regions protruding from different regions of a first side of the device region, respectively, and a plurality of chip pads in the first and second chip pad regions, each chip pad of the plurality of chip pads being connected to the substrate pads by a corresponding wire, and the first and second semiconductor chips are stacked such that the first and second chip pad regions face a same horizontal direction and do not overlap each other in a stacking direction.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a perspective view illustrating a semiconductor package according to an embodiment.

FIGS. 2A and 2B are a plan view and a side cross-sectional view, respectively, illustrating the semiconductor package of FIG. 1.

FIGS. 3A and 3B are plan views of first and second semiconductor chips in a semiconductor package according to an embodiment, respectively.

FIG. 4 is a plan view illustrating a wafer for the first and second semiconductor chips of FIGS. 3A and 3B.

FIGS. 5A to 5C are perspective views of major processes illustrating a method for manufacturing the semiconductor package of FIG. 1.

FIGS. 6A and 6B are plan views illustrating first and second wafers for first and second semiconductor chips, respectively.

FIGS. 7 and 8 are cross-sectional side views illustrating semiconductor packages according to various embodiments.

FIGS. 9 and 10 are cross-sectional side views illustrating semiconductor packages according to various embodiments.

FIG. 11 is a perspective view illustrating a semiconductor package according to an embodiment.

FIG. 12 is a side view illustrating the semiconductor package of FIG. 11.

FIGS. 13A to 13E are perspective views of major processes illustrating a method for manufacturing the semiconductor package of FIG. 11.

FIG. 14 is a cross-sectional side view illustrating a semiconductor package according to an embodiment.

### DETAILED DESCRIPTION

Hereinafter, various embodiments will be described with reference to the attached drawings.

Items described in the singular herein may be provided in plural, as can be seen, for example, in the drawings. Thus, the description of a single item that is provided in plural should be understood to be applicable to the remaining plurality of items unless context indicates otherwise.

As used herein the term “overlap” is intended to mean that an element is over, on, or aside at least a part of another element. The elements may be touching or not. An element need not cover an entire surface of an element to be considered “overlapping”. The term is intended to encompass one element overlapping all or any part of another element.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise.

It will be understood that, although the terms first, second, etc. may be used herein to describe various elements, components, or materials, these elements, components, or materials should not be limited by these terms. Unless the context indicates otherwise, these terms are only used to distinguish one element, component, or material from another element, component, or material, for example as a naming convention.

The various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be provided on or near an external surface of the device and may have a planar surface having dimensions greater than wiring (e.g., X-Y horizontal dimensions of a pad are both greater than the width of an internal wiring to which it is connected) to promote an electrical connection to a further terminal, such as a bump or solder ball, and/or an external wiring.

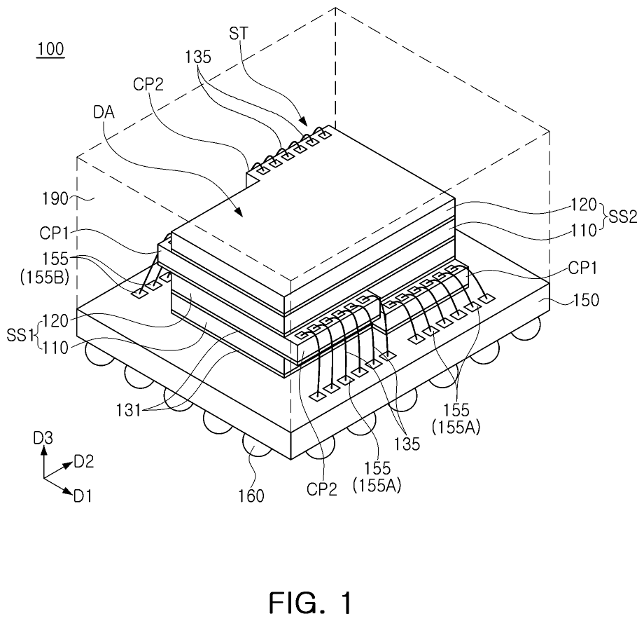

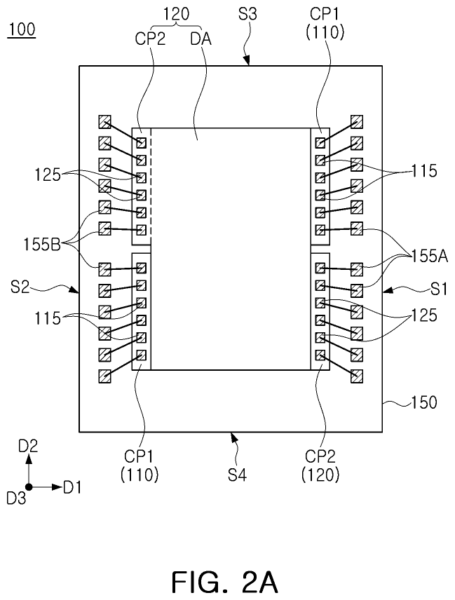

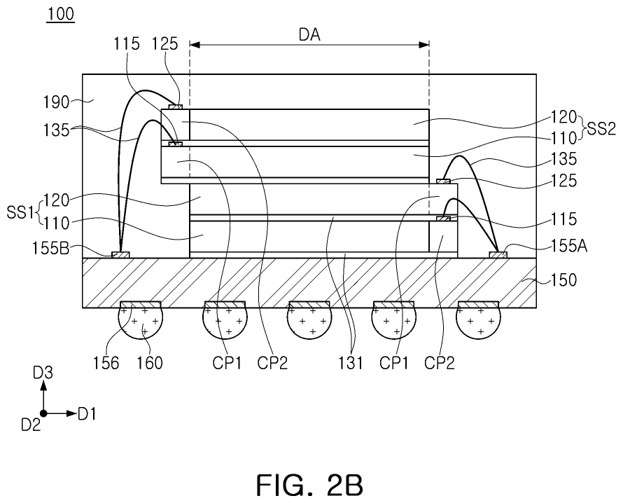

FIG. 1 is a perspective view illustrating a semiconductor package according to an embodiment, and FIGS. 2A and 2B are a plan view and a side cross-sectional view, respectively, illustrating the semiconductor package of FIG. 1.

Referring to FIGS. 1, 2A and 2B, a semiconductor package 100 according to the present embodiment may include a package substrate 150, a chip stack ST in which a plurality of first semiconductor chips 110 and a plurality of second semiconductor chips 120 are stacked on the package substrate 150, and a molding film 190 surrounding the chip stack ST on the package substrate 150.

The package substrate 150 may include, for example, a printed circuit board (PCB). The package substrate 150 may include substrate pads 155 disposed at an upper surface of the package substrate 150, and connection pads 156 disposed on a lower surface of the package substrate 150. External connection terminals 160 configured to electrically connect an external device and the semiconductor package 100 may be disposed on the connection pads 156. The external connection terminals 160 may be, for example, a solder ball, a solder bump, or a solder pillar.

The chip stack ST may include the plurality of first semiconductor chips 110 and the plurality of second semiconductor chips 120, stacked on the package substrate 150 in a vertical direction (D3). In the present embodiment, it is illustrated that the chip stack ST includes two first semiconductor chips 110 and two second semiconductor chips 120, i.e., four semiconductor chips, but is not limited thereto. For example, the chip stack ST may include a smaller number or a larger number of (e.g., eight or twelve) semiconductor chips.

Stacked first and second semiconductor chips 110 and 120 may be bonded by an adhesive member 131. The adhesive member 131 may be provided between adjacent semiconductor chips 110 and 120. Similarly, the adhesive member 131 may be disposed between a lower surface of a first lowermost semiconductor chip 110 among the plurality of semiconductor chips and the upper surface of the package substrate 150, such that the chip stack ST may be attached on the package substrate 150. For example, the adhesive member 131 may be a die attach film (DAF).

In the present embodiment, the first semiconductor chips 110 and the second semiconductor chips 120 may be semiconductor chips of the same type, but may include chip pad regions (CP1 and CP2) of different shapes, respectively. This will be described later.

The first and second semiconductor chips 110 and 120 may be semiconductor memory chips. The memory chip may be, for example, a volatile memory semiconductor chip such as a DRAM (Dynamic Random Access Memory) or an SRAM (Static Random Access Memory), or a nonvolatile memory semiconductor chip such as a phase-change random access memory (PRAM), a magnetoresistive random access memory (MRAM), a ferroelectric random access memory (FeRAM), or a resistive random access memory (RRAM). In some embodiments, the memory chip may be a flash memory, for example, a NAND flash memory.

In other embodiments, the chip stack ST may include at least one different type of semiconductor chip. For example, some of the semiconductor chips may be a memory chip. Other of the semiconductor chips may be a logic chip. For example, the logic chip may be a central processing unit (CPU) chip, a graphics processing unit (GPU) chip, or an application processor (AP) chip.

As described above, the first semiconductor chips 110 and the second semiconductor chips 120, in the present embodiment, may be semiconductor chips of the same type, but may have different shapes in plan view.

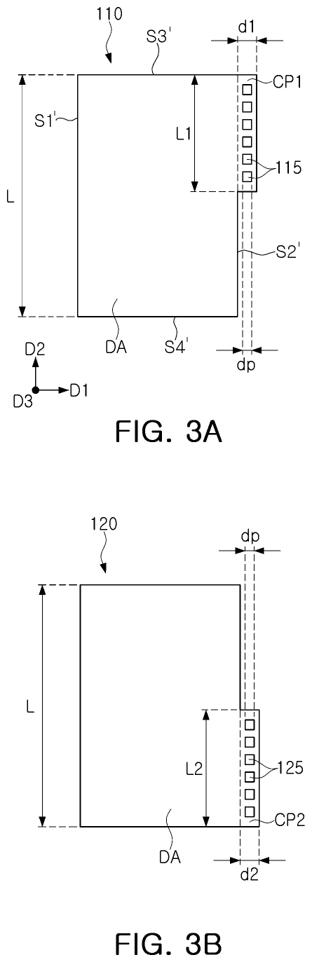

FIGS. 3A and 3B are plan views of first and second semiconductor chips 110 and 120 in a semiconductor package according to an embodiment, respectively.

Referring to FIGS. 3A and 3B together with FIG. 1, the first and second semiconductor chips 110 and 120 in the present embodiment may have the same device region DA in which an integrated circuit is implemented. In some embodiments, the device regions DA of the first and second semiconductor chips 110 and 120 may have the same dimensions. For example, the device regions DA of the first and second semiconductor chips 110 and 120 may have the same shapes and the same areas.

First and second chip pad regions CP1 and CP2 in which chip pads 115 and 125 of the first semiconductor chips 110 and the second semiconductor chips 120 are disposed may be included, and the first and second chip pad regions CP1 and CP2 may have different structures. The chip pads 115 and 125 may be configured to be electrically connected to an integrated circuit of each device region DA. The chip pads 115 and 125 may be disposed in each of the first and second chip pad regions CP1 and CP2 in a second direction (D2). For example, the integrated circuit may constitute a memory circuit or a logic circuit.

As used herein, components described as being “electrically connected” are configured such that an electrical signal can be transferred from one component to the other (although such electrical signal may be attenuated in strength as it is transferred and may be selectively transferred).

The first and second chip pad regions CP1 and CP2 may protrude from different first and second regions on the same side of the device region DA of each of the first and second semiconductor chips 110 and 120. In this case, the first and second regions may not have overlapping portions. In plan view, the first semiconductor chip 110 may have an L-shape, and the second semiconductor chip 120 may have an inverted L-shape (see FIGS. 3A and 3B).

When these first and second semiconductor chips 110 and 120 are stacked such that the device regions DA overlap each other (see FIG. 2A), the first and second chip pad regions CP1 and CP2 may not overlap in the stacking direction (D3). Even when the first semiconductor chip 110 is stacked below the second semiconductor chip 120 such that the device regions DA almost completely overlap, the second chip pad region CP2 may not cover the first chip pad region CP1 (see FIG. 1 and FIG. 2A).

In this manner, the chip stack ST in the present embodiment may open the first and second chip pad regions CP1 and CP2 without offsetting them in the first direction (D1) (i.e., without step-wise stacking). Therefore, the chip stack ST in the present embodiment may be implemented compactly without additional space consumption (or an area occupied) due to stacking step-wise.

Referring to FIGS. 3A and 3B, lengths L1 and L2 of the first and second chip pad regions CP1 and CP2 may be equal to each other, and a sum of the lengths (L1+L2) may be less than a total length L of one side (a first side of the device region). The difference between the total length L and the sum of the two lengths (L1+L2), i.e., a gap between the first and second chip pad regions CP1 and CP2, may be determined by a width cut during a process of dicing the first and second semiconductor chips 110 and 120.

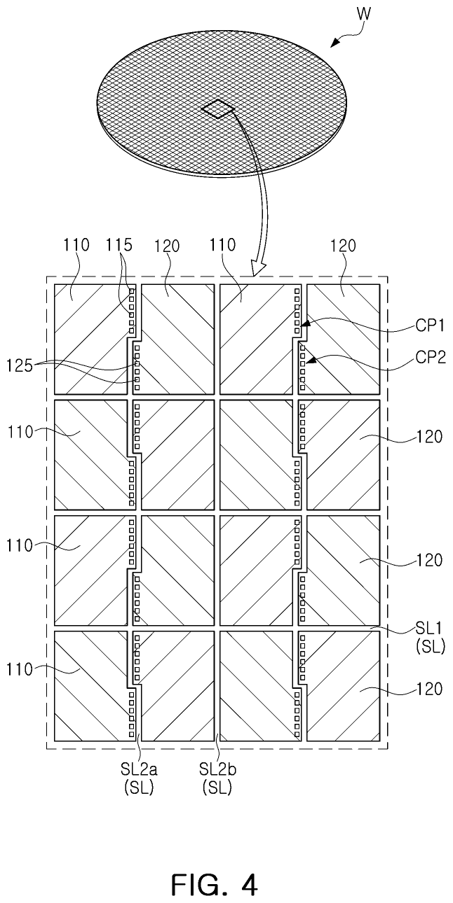

In the present embodiment, when the same device region DA is rectangular in plan view, a long side (S1′ or S2′) of the device region DA has a length, greater than a length of a short side (S3′ or S4′), such that the first and second chip pad regions CP1 and CP2, not overlapping, may be more easily disposed on the long side (S1′ or S2′) than on the short side (S3′ or S4′) (see FIG. 4). For example, a ratio of the long side to the short side of the device region DA may be 1.5:1 or more (in a specific example, 2:1 or more).

Referring to FIGS. 3A and 3B, protruding lengths d1 and d2 of the first and second chip pad regions CP1 and CP2 may be equal to each other, and each thereof may be greater than a width dp of each of the chip pads 115 and 125. The chip pads 115 and 125 may be located on the first and second chip pad regions CP1 and CP2. Even when the device region DA of the first semiconductor chip 110 is covered by the device region DA of the second semiconductor chip 120, the chip pads 115 on the first chip pad region CP1 may be opened such that bonding of a wire 135 is ensured (see FIGS. 1, 2A and 2B).

In the present embodiment, referring to FIG. 1, FIG. 2A and FIG. 2B, the package substrate 150 may have a first side S1 and a second side S2, facing in the first direction (D1) a second horizontal direction, and a third side S3 and a fourth side S4, facing in the second direction (D2), a first horizontal direction. The substrate pads 155 may include first substrate pads 155A and second substrate pads 155B, respectively disposed along the first side S1 and the second side S2, adjacent to the first side S1 and the second side S2.

The chip stack ST may be disposed between the first substrate pads 155A and the second substrate pads 155B on the package substrate 150. The chip stack ST in the present embodiment may be described as including two sub-stacks SS1 and SS2 respectively including a pair of first and second semiconductor chips 110 and 120.

First semiconductor chips 110 of first and second sub-stacks SS1 and SS2 have the same shape (structure) as each other, and second semiconductor chips 120 of the first and second sub-stacks SS1 and SS2 have the same shape (structure) as each other. In plan view, the first and second semiconductor chips 110 and 120 of the second sub-stack SS2 can be understood as being arranged 180 degrees rotation relative to the first and second semiconductor chips 110 and 120 of the first sub-stack SS1. In this specification, the “first and second semiconductor chips 110 and 120” of the second sub-stack SS2 may be referred to as “third and fourth semiconductor chips” respectively to distinguish them from the first and second semiconductor chips 110 and 120 of the first sub-stack SS1.

As illustrated in FIGS. 2A and 2B, in the chip stack ST, both the first and second semiconductor chips 110 and 120 may be disposed such that their device regions DA overlap each other, but the first and second sub-stacks SS1 and SS2 may be stacked such that the first and second chip pad regions CP1 and CP2 face opposite directions (+D1 and −D1) in the first direction (D1).

Specifically, in the first sub-stack SS1, the first and second semiconductor chips 110 and 120 may be disposed such that the device regions DA overlap each other, and their first and second chip pad regions CP1 and CP2 face the first side S1 of the package substrate 150. Similarly, in the second sub-stack SS2, the first and second semiconductor chips 110 and 120 may be disposed such that the device regions DA overlap each other, and the first and second chip pad regions CP1 and CP2 face the second side S2 of the package substrate 150.

As illustrated in FIG. 2A, even when all the first and second semiconductor chips 110 and 120 are stacked such that the device regions DA almost overlap, the chip pads 115 and 125 of the first and second chip pad regions CP1 and CP2 may be opened in an upward direction.

Therefore, even without substantial stacking step-wise, the chip pads 115 and 125 of the first and second semiconductor chips 110 and 120 of the first sub-stack SS1 may be electrically connected to the first substrate pads 155A using wires 135, and similarly, the chip pads 115 and 125 of the first and second semiconductor chips 110 and 120 of the second sub-stack SS2 may be electrically connected to the second substrate pads 155B using wires 135.

The first and second sub-stacks SS1 and SS2 in the present embodiment may be respectively stacked such that sides, other than sides on which the chip pad regions CP1 and CP2 are located, are substantially coplanar with each other. In the present embodiment, all of the first and second semiconductor chips 110 and 120 may be stacked such that sides of the chip stack ST in the second direction (D2) are substantially coplanar.

In the present embodiment, it is illustrated that the device regions DA of all of the first and second semiconductor chips 110 and 120 have the same area and the same shape, and are substantially completely overlapped, but even when the device regions DA have the same area and the same shape, in some embodiments, at least some of the semiconductor chips may be additionally stacked to be offset for a more stable connection space.

The molding film 190 may be provided on the package substrate 150. The molding film 190 may cover the chip stack ST and the wire 135 on the package substrate 150. A side surface of the molding film 190 may be substantially coplanar with a side surface of the package substrate 150. For example, the molding film 190 may include an insulating polymer such as an epoxy-based molding compound (EMC).

In this manner, the chip stack ST in the present embodiment may reduce the occupied area of the chip stack ST without additional space consumption due to stacking step-wise, and furthermore, may reduce a size of the semiconductor package 100. In the present embodiment, it is illustrated that the first and second sub-stacks SS1 and SS2 are stacked in the same order of the first semiconductor chip 110 and the second semiconductor chip 120, but are not limited thereto, and at least one sub-stack may include the first and second semiconductor chips 110 and 120 stacked in a different order.

A chip stack ST according to the present embodiment may be implemented by the first and second semiconductor chips 110 and 120 that may be the same type of semiconductor chip, but have different shapes, in plan view. In some embodiments, the first and second semiconductor chips 110 and 120 may be obtained from the same wafer. FIG. 4 is a plan view illustrating a wafer W for the first and second semiconductor chips 110 and 120 of FIG. 3A and FIG. 3B.

Referring to an enlarged view of FIG. 4, it is illustrated that a 4×4 chip array is a portion of a wafer W. The 4×4 chip array includes eight pairs of first and second semiconductor chips 110 and 120 (4×2 chip array). In the wafer W, the first and second semiconductor chips 110 and 120 may be disposed such that first and second chip pad regions CP1 and CP2 are located on opposite sides of pairs of adjacent columns. The first semiconductor chips 110 located in odd-numbered columns may have first chip pad regions CP1 protruding from a first region on one side (a first side of the device region), and the second semiconductor chips 120 located in even-numbered columns may have second chip pad regions CP2 protruding from a second region on the one side/first side of the device region.

The first and second semiconductor chips 110 and 120 of FIG. 4 may be cut along a scribe lane SL. The scribe lane SL may include a scribe lane SL1 in a horizontal direction, and first and second scribe lanes SL2a and SL2b in a vertical direction. Each pair of first scribe lanes SL2a may extend in a curved shape along between the first and second chip pad regions CP1 and CP2. A dicing process including these curved scribe lanes may be performed by ‘plasma dicing.’

The scribe lanes SL between the undiced chips may include areas of the wafer W in which no circuits (e.g., no transistors) are formed and/or no circuits (e.g., no transistors) are formed that are part of the integrated circuits of the undiced chips C.

The plasma dicing may be a method of dividing the wafer into chips by forming a mask to cover chip regions (device region and chip pad region) and then etching a region (e.g., scribe lane) not covered by the mask with plasma. Because the plasma etching may be applied to the entire wafer, a plurality of chips may be separated simultaneously. For example, the plasma etching may use a fluorine-based gas that may be highly reactive with the wafer, such as SF₆ or CF₄.

In this manner, in the plasma dicing, the mask may be relatively freely patterned, and an exposed region may be simultaneously etched by plasma application, such that scribe lanes including the second scribe lane may be easily removed, as illustrated in FIG. 4.

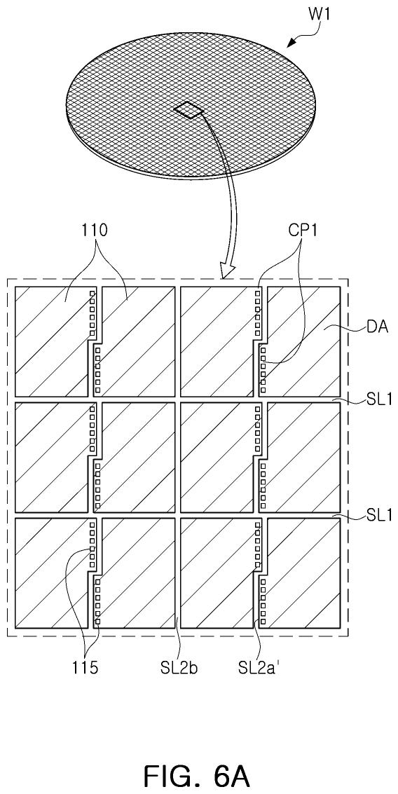

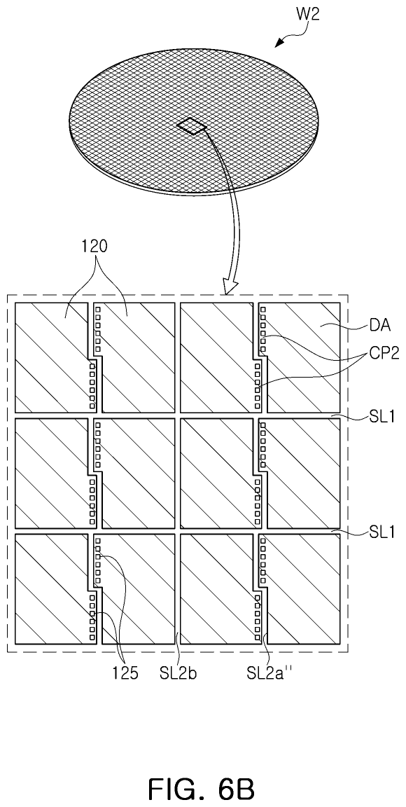

In the present embodiment, the first and second semiconductor chips 110 and 120 of the same type having different shapes may be manufactured from one wafer. The first and second semiconductor chips 110 and 120 have the same device region DA, as described in FIG. 3A and FIG. 3B, and the first and second chip pad regions CP1 and CP2 of the first semiconductor chips 110 and the second semiconductor chips 120 may protrude from the first and second regions, different from each other, on the same side of the respective device regions DA. In another embodiment, the first and second semiconductor chips 110 and 120 may be formed on different wafers W1 and W2, and, in this case, different types of scribe lanes may be configured (see FIGS. 6A and 6B).

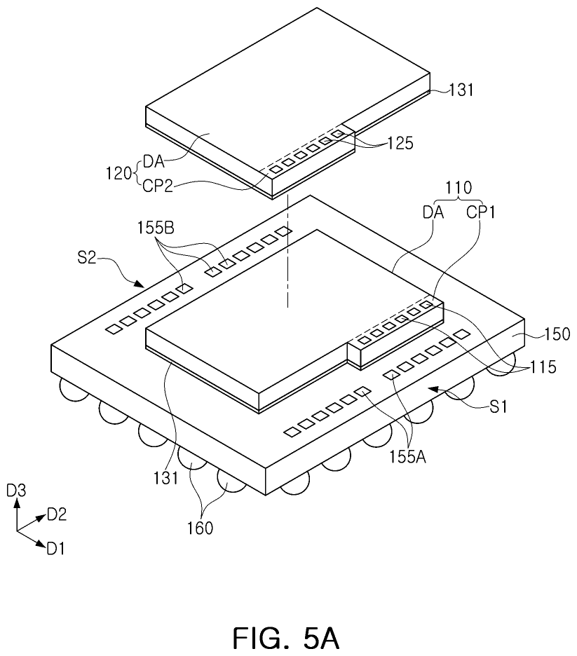

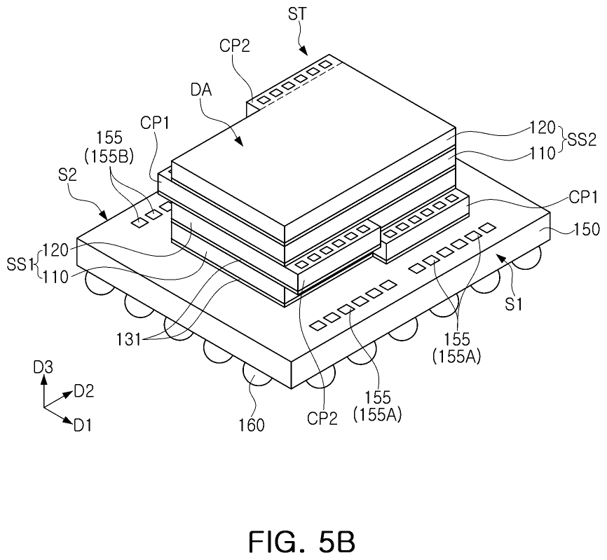

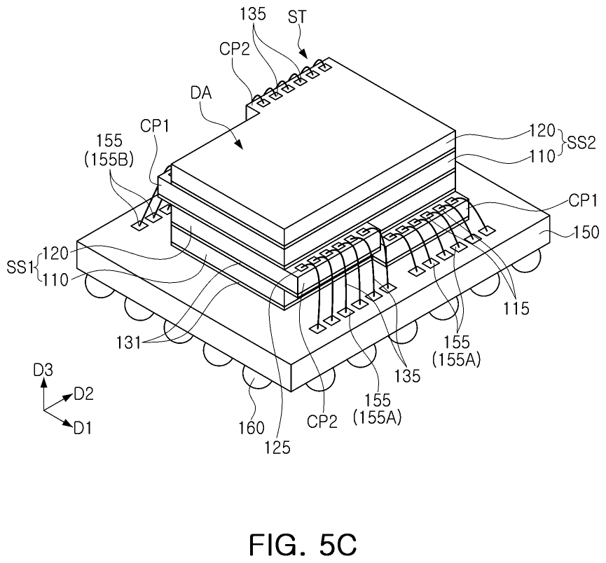

FIGS. 5A to 5C are perspective views of major processes illustrating a method for manufacturing the semiconductor package of FIG. 1.

Referring to FIG. 5A, a first sub-stack SS1 including a pair of first and second semiconductor chips 110 and 120 may be formed on a package substrate 150.

The package substrate 150 has a first side S1 and a second side S2, facing each other in the first direction (D1), and first substrate pads 155A and second substrate pads 155B may be disposed to be adjacent to the first side S1 and the second side S2, respectively, and the first semiconductor chip 110 may be disposed between the first substrate pads 155A and the second substrate pads 155B on the package substrate 150 such that a first chip pad region CP1 faces the first side S1. The first semiconductor chip 110 may be bonded to an upper surface of the package substrate using an adhesive member 131 such as a DAF. Next, the second semiconductor chip 120 may be stacked on the first semiconductor chip 110 such that device regions DA overlap each other and a second chip pad region CP2 faces the first side S1. In another embodiment, a stacking order of the first and second semiconductor chips 110 and 120 may be changed in a direction, opposite thereto.

Next, referring to FIG. 5B, a desired chip stack ST may be formed by forming a second sub-stack SS2 including a different pair of first and second semiconductor chips 110 and 120 on the first sub-stack SS1.

A process of forming the second sub-stack SS2 may be performed similarly to the first sub-stack SS1. The second sub-stack SS2 may be formed on the first sub-stack SS1 by sequentially stacking the first and second semiconductor chips such that the device regions DA overlap each other. The first and second semiconductor chips 110 and 120 of the second sub-stack SS2 may be stacked such that the first and second chip pad regions CP1 and CP2 face the second side S2. As a result, a chip stack including four semiconductor chips 110 and 120 may be configured. The device regions DA of the four semiconductor chips 110 and 120 may all overlap, while the protruding first and second chip pad regions CP1 and CP2 may be disposed such that the first and second sub-stacks SS1 and SS2 face different facing sides S1 and S2 of the package substrate 150. In addition, the first and second chip pad regions of the first and second sub-stacks SS1 and SS2 may not overlap each other in the stacking direction (D3). In another embodiment, the stacking order of the first and second semiconductor chips 110 and 120 may be changed in a direction, opposite thereto.

Next, referring to FIG. 5C, chip pads 115 and 125 of the first and second semiconductor chips 110 and 120 may be electrically connected to the first and second substrate pads 155A and 155B by wires 135, respectively.

The chip pads 115 and 125 of the first and second semiconductor chips 110 and 120 of the first sub-stack SS1 may be electrically connected to the first substrate pads 155A by using the wires 135, and similarly, the chip pads 115 and 125 of the first and second semiconductor chips 110 and 120 of the second sub-stack SS2 may be electrically connected to the second substrate pads 155B by using the wires 135.

In each of the first and second sub-stacks SS1 and SS2, the first chip pad region CP1 of the first semiconductor chip 110 located below the second semiconductor chip 120 may be opened without being covered by the second chip pad region CP2. Therefore, even when the device regions DA of all the first and second semiconductor chips 110 and 120 almost overlap each other, the chip pads 115 and 125 of the first and second chip pad regions CP1 and CP2 may be opened in an upward direction, and an easy wire bonding process may be performed. In addition, because there may be no additional space consumption due to stacking step-wise, an occupied area of the chip stack ST may be reduced. Next, the semiconductor package 100, illustrated in FIG. 1 and FIG. 2A, may be manufactured by forming a molding film 190 covering the chip stack ST and the wires 135 on the package substrate 150.

In the previous embodiment (see FIG. 4), it is illustrated that the first and second semiconductor chips 110 and 120 in the present embodiment are provided as a diced form of a single wafer W, but the first and second semiconductor chips 110 and 120 may also be manufactured from two wafers W1 and W2, respectively.

FIGS. 6A and 6B are plan views illustrating first and second wafers for first and second semiconductor chips, respectively.

Referring to FIGS. 6A and 6B, it is illustrated that a 4×3 chip array is a portion of first and second wafers W1 and W2, and the first and second wafers W1 and W2 may include first and second semiconductor chips 110 and 120 having different shapes in plan view, respectively.

First, referring to FIG. 6A, in a first wafer W1, first semiconductor chips 110 may be disposed such that first chip pad regions CP1 are located on opposite sides of a pair of adjacent columns. The first semiconductor chips 110 may have the first chip pad regions CP1 protruding from first regions of the first sides of the device region. Similarly, referring to FIG. 6B, in a second wafer W2, second semiconductor chips 120 may be disposed such that second chip pad regions CP2 are located on opposite sides of a pair of adjacent columns. The second semiconductor chips 120 may have the second chip pad regions CP2 protruding from second regions of the first sides of the device region. Arrangement of these chips may be achieved by changing the design and process of the semiconductor chips (positions of a device region and a chip pad region) such that chip boundaries are different between facing sides, and by forming a curved first scribe lane (SL2a′ and SL2a″) along the chip boundaries, a semiconductor chip of a desired shape may be manufactured.

In this manner, first and second semiconductor chips 110 and 120 of the same type having different shapes may be manufactured from the different wafers W1 and W2, and the first and second semiconductor chips 110 and 120 may be appropriately selected to form a desired chip stack ST, and a semiconductor package 100 having an optimized size may be provided (see FIGS. 5A to 5C).

In the preceding embodiments, it is illustrated that the chip stack ST includes two first semiconductor chips 110 and two second semiconductor chips 120, for example, four semiconductor chips, but are not limited thereto. For example, the chip stack ST may include a smaller number or a larger number (e.g., 8 or 12) of semiconductor chips.

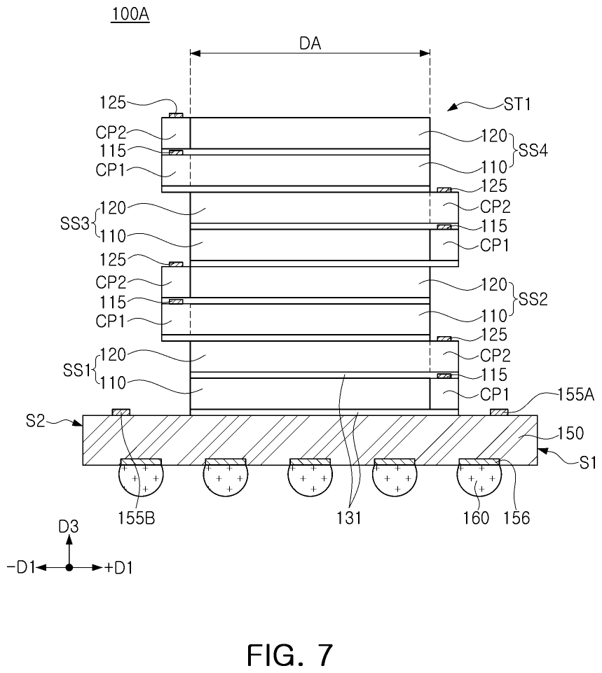

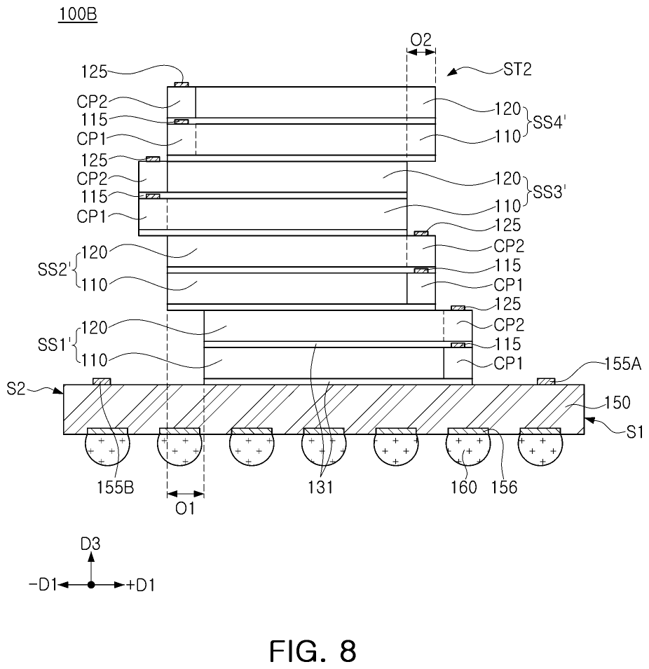

FIGS. 7 and 8 illustrate semiconductor packages according to various embodiments, in which chip stacks in which 8 semiconductor chips are stacked.

Semiconductor packages 100A and 100B according to the present embodiment are illustrated as a structure in which wires and molding films are omitted for convenience of explanation. In this case, it can be understood that first and second semiconductor chips 110 and 120 are identical to the first and second semiconductor chips 110 and 120 (FIGS. 1 to 6) described in the previous embodiments, respectively.

Referring to FIG. 7, a semiconductor package 100A according to the present embodiment may include a chip stack ST1 in which four first semiconductor chips 110 and four second semiconductor chips 120 are stacked.

The chip stack ST1 in the present embodiment may include first to fourth sub-stacks SS1, SS2, SS3, and SS4 respectively including a pair of first and second semiconductor chips 110 and 120.

The first semiconductor chips 110 of the first to fourth sub-stacks SS1, SS2, SS3, and SS4 may have the same shape (or structure) as each other, and the second semiconductor chips 120 of the first to fourth sub-stacks SS1, SS2, SS3, and SS4 may have the same shape (or structure) as each other. In plan view, it can be understood that the first and second semiconductor chips 110 and 120 of the second and fourth sub-stacks SS2 and SS4 are disposed to rotate the first and second semiconductor chips 110 and 120 of the first and third sub-stacks SS1 and SS3 in 180 degrees.

As illustrated in FIG. 7, in the chip stack ST1, both the first and second semiconductor chips 110 and 120 may be disposed such that device regions DA thereof overlap each other, but the first and third sub-stacks SS1 and SS3 may be stacked such that respective first and second chip pad regions CP1 and CP2 thereof face a first side S1 of a package substrate 150, and conversely, the second and fourth sub-stacks SS2 and SS4 may be stacked such that respective first and second chip pad regions CP1 and CP2 thereof face a second side S2 of the package substrate 150.

In the chip stack ST1 according to the present embodiment, even when the device regions DA of all the first and second semiconductor chips 110 and 120 overlap each other, the first and second chip pad regions CP1 and CP2 of one sub-stack (e.g., SS2 ) may not overlap the first and second chip pad regions CP1 and CP2 of adjacent other sub-stacks (e.g., SS1, SS3 ) in the stacking direction (D3).

The first and second chip pad regions CP1 and CP2 of the first sub-stack SS1 may overlap the first and second chip pad regions CP1 and CP2 of the non-adjacent third sub-stack SS3, and similarly, the first and second chip pad regions CP1 and CP2 of the second sub-stack SS2 may overlap the first and second chip pad regions CP1 and CP2 of the non-adjacent fourth sub-stack SS4. Even when there is an overlap of the first and second chip pad regions CP1 and CP2 in the chip stack ST1, because they may be spaced apart by at least thicknesses of three semiconductor chips, it may not be a significant obstacle in performing wire bonding.

Referring to FIG. 8, a semiconductor package 100B according to the present embodiment may include a chip stack ST2 in which four first semiconductor chips 110 and four second semiconductor chips 120 are stacked, similar to the embodiment of FIG. 7. The chip stack ST2 may include first to fourth sub-stacks SS1′, SS2′, SS3′, and SS4′ respectively including a pair of first and second semiconductor chips 110 and 120.

The first semiconductor chips 110 of the first to fourth sub-stacks SS1′, SS2′, SS3′, and SS4′ may have the same shape (structure) as each other, and the second semiconductor chips 120 of the first to fourth sub-stacks SS1′, SS2′, SS3′, and SS4′ may have the same shape (structure) as each other.

In each of the first to fourth sub-stacks SS1′, SS2′, SS3′, and SS4′, similarly to the previous embodiments, the first and second semiconductor chips 110 and 120 may be stacked such that device regions DA thereof overlap each other, but the first and second chip pad regions CP1 and CP2 may be stacked to not overlap while facing the same side of a package substrate 150.

In the present embodiment, the first and second chip pad regions CP1 and CP2 of the first and second sub-stacks SS1′ and SS2′ may be disposed to face a first side S1 of the package substrate 150, and the first and second chip pad regions CP1 and CP2 of the third and fourth sub-stacks SS3′ and SS4′ may be disposed to face a second side S2 of the package substrate 150.

In addition, the chip stack ST2 in the present embodiment may partially introduce a step-wise stacking method. The second sub-stack SS2′ may be offset-stacked on the first sub-stack SS1′ by a first distance O1 in a negative first direction (−D1), and the fourth sub-stack SS4′ may be offset-stacked on the third sub-stack SS3′ by a second distance O2 in a positive first direction (+D1). The third sub-stack SS3′ may be disposed such that the second sub-stack SS2′ and all device regions DA overlap each other.

In this manner, in the chip stack ST2 in the present embodiment, the first and second semiconductor chips 110 and 120 do not overlap the first and second chip pad regions CP1 and CP2 of adjacent other semiconductor chips, but the first and second chip pad regions CP1 and CP2 of the second sub-stack SS2′ may overlap the non-adjacent fourth sub-stack SS4′.

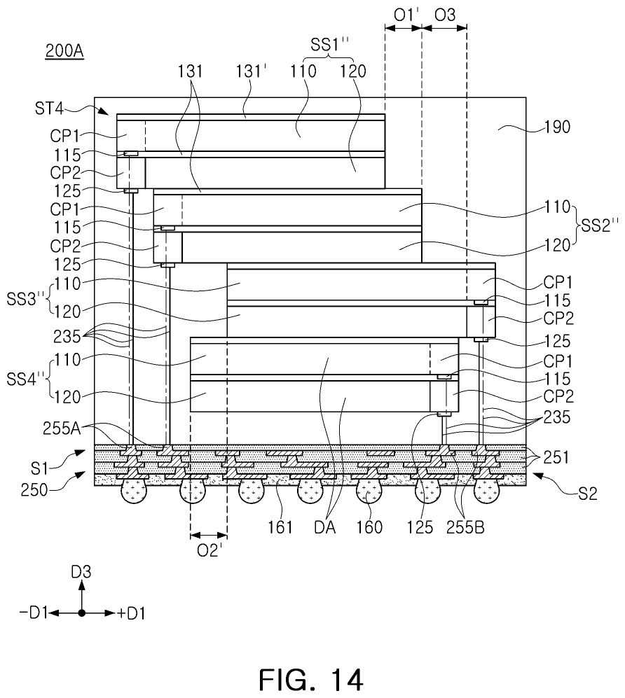

In the present embodiment, even when the first and second chip pad regions CP1 and CP2 of the second sub-stack SS2′ overlap the device region DA of the fourth sub-stack SS4′ in the stacking direction (D3), they may be spaced apart by at least thicknesses of two semiconductor chips, such that it may not be a significant obstacle to implementing wire bonding. In some embodiments, the overlap of the device region DA of the non-adjacent fourth sub-stack SS4′ with the first and second chip pad regions CP1 and CP2 of the second sub-stack SS2′ may also be prevented by offsetting the third sub-stack SS3′ in the negative first direction (−D1) (see FIG. 14).

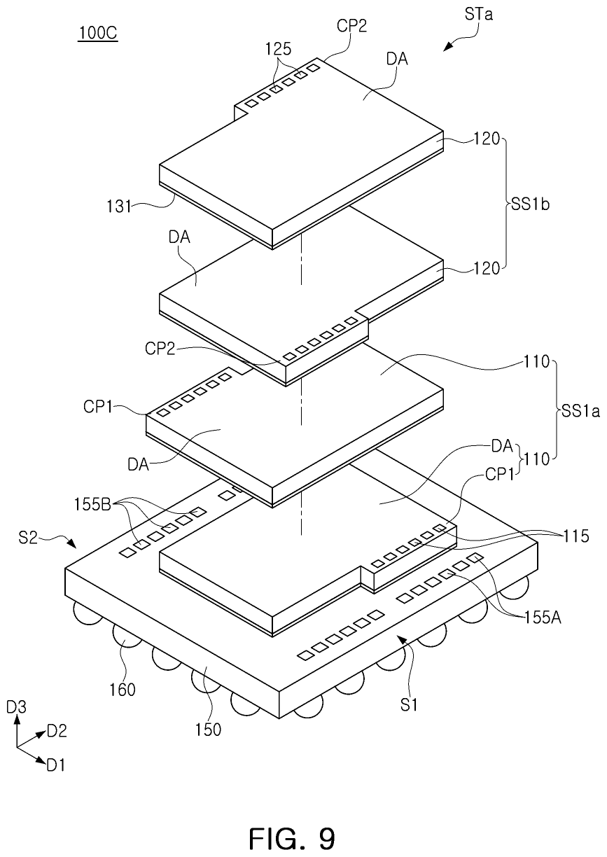

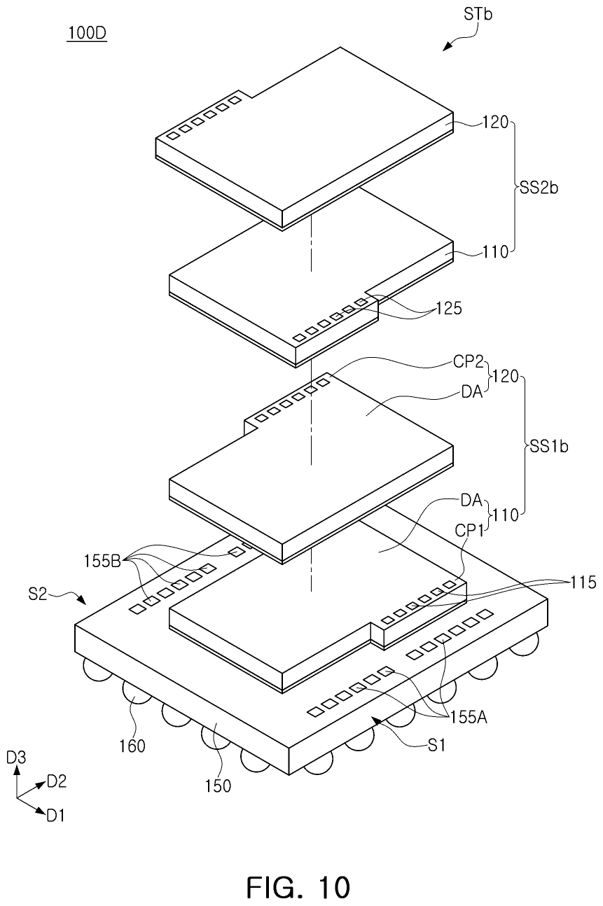

FIGS. 9 and 10 are cross-sectional side views illustrating semiconductor packages according to various embodiments.

It is illustrated that semiconductor packages 100C and 100D according to the present embodiment have a structure in which a wire and a molding film are omitted for convenience of explanation. In this case, it can be understood that first and second semiconductor chips 110 and 120 are identical to the first and second semiconductor chips 110 and 120 (of FIGS. 1 to 6) described in the previous embodiment, respectively.

Referring to FIG. 9, a semiconductor package 100C according to the present embodiment may include chip stacks STa in which two first semiconductor chips 110 and two second semiconductor chips 120 are stacked, similar to the previous embodiment (FIG. 1), but in the chip stack STa in the present embodiment, four semiconductor chips may be stacked in a different order. For example, if a stacking order of the chip stack ST in the semiconductor package illustrated in FIG. 1 (see FIG. 5C) is defined as \textcircled{1}-\textcircled{2}-\textcircled{3}-\textcircled{4} according to shapes and arrangement directions of the semiconductor chips, the chip stack STa in the present embodiment may be stacked in an order of \textcircled{1}-\textcircled{2}-\textcircled{3}-\textcircled{4}.

In the chip stack STa in the present embodiment, the first and second semiconductor chips 110 and 120 may be stacked such that device regions DA overlap each other, but first and second chip pad regions CP1 and CP2 do not overlap each other in the stacking direction (D3).

Specifically, a first sub-stack SS1a may include two first semiconductor chips 110 stacked such that first chip pad regions CP1 face a first side S1 and a second side S2 of a package substrate 150, respectively. A second sub-stack SS2a may include two second semiconductor chips 120 stacked such that second chip pad regions CP2 face the first side S1 and the second side S2 of the package substrate 150, respectively.

In this manner, similar to the embodiment of FIG. 1, in the semiconductor package 100C according to the present embodiment, the first and second chip pad regions CP1 and CP2 may not overlap in the stacking direction (D3), and all chip pads 115 and 125 may be opened in an upward direction to facilitate a wire bonding connection.

Referring to FIG. 10, a semiconductor package 100D according to the present embodiment includes chip stacks STb in which two first semiconductor chips 110 and two second semiconductor chips 120 are stacked, similarly to the previous embodiments (FIGS. 1 and 9), but in the chip stack STb in the present embodiment, four semiconductor chips may be stacked in a different order. For example, if a stacking order of the chip stack ST of FIG. 1 is defined as \textcircled{1}-\textcircled{2}-\textcircled{3}-\textcircled{4} according to shapes and arrangement directions of the semiconductor chips, the chip stack STb in the present embodiment may be stacked in an order of \textcircled{1}-\textcircled{2}-\textcircled{3}-\textcircled{4}.

In the chip stack STb in the present embodiment, the first and second semiconductor chips 110 and 120 may be stacked such that device regions DA overlap each other, but first and second chip pad regions CP1 and CP2 do not overlap each other in the stacking direction (D3).

Specifically, a first sub-stack SS1b may include a pair of first and second semiconductor chips 110 and 120 stacked such that first and second chip pad regions CP1 and CP2 face a first side S1 and a second side S2 of a package substrate 150, respectively. A second sub-stack SS2a may include a pair of first and second semiconductor chips 110 and 120 stacked such that the first and second chip pad regions CP1 and CP2 face the first side S1 and the second side S2 of the package substrate 150, respectively.

In this manner, similar to the embodiments of FIGS. 1 and 9, the semiconductor package 100D according to the present embodiment may have the first and second chip pad regions CP1 and CP2 not overlapping each other in the stacking direction (D3), and all chip pads 115 and 125 may be opened in an upward direction to facilitate wire bonding connection.

As described in FIGS. 9 and 10, the first and second semiconductor chips may be stacked in various stacking orders and directions to expect similar effects. This change is not limited to a stack structure of four semiconductor chips, and a stack structure of eight semiconductor chips may be implemented by additionally stacking the chip stacks Sta and STb of FIGS. 9 and 10 on the chip stacks Sta and STb of FIGS. 9 and 10.

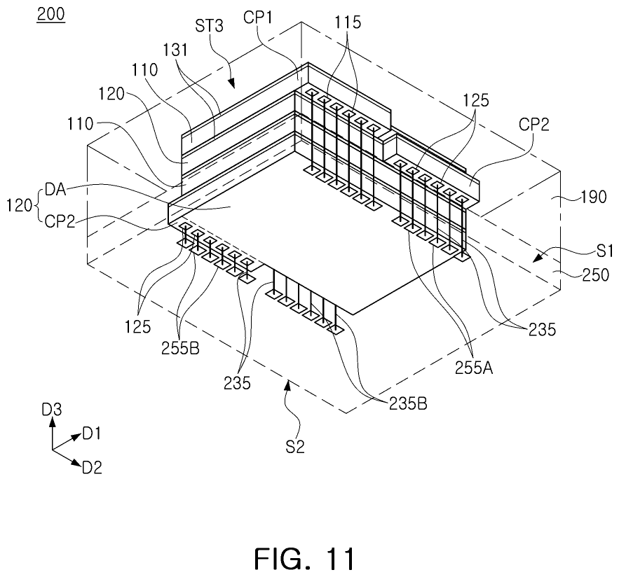

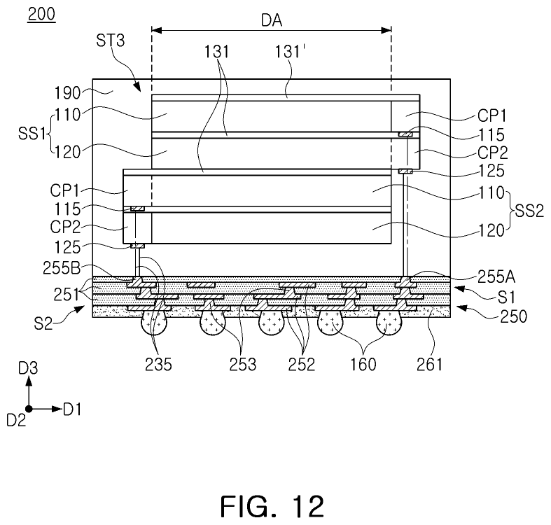

FIG. 11 is a perspective view illustrating a semiconductor package according to an embodiment, and FIG. 12 is a side view illustrating the semiconductor package of FIG. 11. FIG. 11 is a perspective view viewed from a lower surface of a semiconductor package 200, in which a molding film 190 and a package substrate 250 are indicated by dotted lines, such that a connection structure of a chip stack ST3 and a wire 235 is more easily understood.

Referring to FIGS. 11 and 12, a semiconductor package 200 according to the present embodiment may include a package substrate 250, a chip stack ST3 in which a plurality of first semiconductor chips 110 and a plurality of second semiconductor chips 120 are stacked on the package substrate 250, and a molding film 190 surrounding the chip stack ST3 on the package substrate 250.

The chip stack ST3 in the present embodiment can be understood as a form in which the chip stack ST of FIG. 1 is inverted. The chip stack ST3 may be stacked such that chip pads 115 and 125 of the chip stack ST of FIG. 1 face the package substrate 250. The chip stack ST3 may be spaced apart from an upper surface of the package substrate 250. The molding film 190 may have a portion filling a spaced space between the chip stack ST3 and the package substrate 250.

The chip stack ST3 may include a plurality of first semiconductor chips 110 and a plurality of second semiconductor chips 120, stacked in the vertical direction (D3) on the package substrate 250. In the present embodiment, the chip stack ST3 is illustrated as a form including two first semiconductor chips 110 and two second semiconductor chips 120, for example, four semiconductor chips, but is not limited thereto. For example, the chip stack ST3 may include a smaller number or a larger number (e.g., 8 or 12) of semiconductor chips.

The stacked first and second semiconductor chips 110 and 120 may be bonded by an adhesive member 131. The adhesive member 131 may be provided between adjacent semiconductor chips 110 and 120. The adhesive member 131′ may also be disposed at an upper surface of the chip stack ST3, i.e., an upper surface of the first semiconductor chip 110 which may be on the uppermost level, but unlike other adhesive members 131, at least a portion thereof may be removed.

Similar to the previous embodiments, the first and second semiconductor chips 110 and 120 may have the same device region DA in which an integrated circuit is implemented. The chip pads 115 and 125 of the first semiconductor chips 110 and the second semiconductor chips 120 may be disposed, and first and second chip pad regions CP1 and CP2 may protrude from different first and second regions on the same side of the device region DA of each of the first and second semiconductor chips 110 and 120. In this case, the first and second regions may not have overlapping portions.

In the chip stack ST3, the first and second semiconductor chips 110 and 120 may be disposed such that the first and second chip pad regions CP1 and CP2 face the upper surface of the package substrate 250, as described above. The first and second semiconductor chips 110 and 120 may be disposed such that the device regions DA overlap each other, while the first and second chip pad regions CP1 and CP2 do not overlap in the stacking direction (D3). Even though the second semiconductor chip 120 is stacked below the first semiconductor chip 110, the first chip pad region CP1 and the second chip pad region CP2 may be opened toward the upper surface of the package substrate 250.

In this manner, the chip stack ST3 in the present embodiment may be configured such that the first and second chip pad regions of the first and second semiconductor chips may be both opened in a downward direction without stacking step-wise.

The chip stack ST3 in the present embodiment may be described as including two sub-stacks SS1 and SS2 each including a pair of the first and second semiconductor chips 110 and 120. Based on the upper surface of the package substrate 250, a first sub-stack SS1 may be disposed on a second sub-stack SS2. In plan view, the first and second semiconductor chips 110 and 120 of the second sub-stack SS2 can be understood as the first and second semiconductor chips 110 and 120 of the first sub-stack SS1 being disposed with 180 degrees rotation, respectively.

In the present embodiment, the package substrate 250 may have a first side S1 and a second side S2, facing each other in the first direction (D1), and substrate pads 155 may include first substrate pads 255A and second substrate pads 255B respectively adjacent to the first side S1 and the second side S2 and disposed along the first side S1 and the second side S2. The chip stack ST3 may be disposed between the first substrate pads 255A and the second substrate pads 255B on the package substrate 250.

In the first sub-stack SS1, the first and second semiconductor chips 110 and 120 may be disposed such that the device regions DA overlap each other, and the first and second chip pad regions 115 and 125 face the first side S1 of the package substrate 250. Similarly, in the second sub-stack SS2, the first and second semiconductor chips 110 and 120 may be disposed such that the device regions DA overlap each other, and the first and second chip pad regions 115 and 125 face the second side S2 of the package substrate 250.

In this manner, in the chip stack ST3, even if all the first and second semiconductor chips 110 and 120 may be stacked such that their device regions DA almost overlap, the chip pads 115 and 125 of the first and second chip pad regions CP1 and CP2 may be opened in a downward direction.

In the present embodiment, the first and second substrate pads 255A and 255B may be disposed in a region overlapping the first and second chip pad regions CP1 and CP2 of the first and second sub-stacks SS1 and SS2 on the upper surface of the package substrate 250. The chip pads 115 and 125 may be connected to the first and second substrate pads 255A and 255B, respectively, by wires 235 formed almost vertically.

Specifically, the chip pads 115 and 125 of the first and second semiconductor chips 110 and 120 of the first sub-stack SS1 may be electrically connected to the first substrate pads 255A using vertical wires 235, and similarly, the chip pads 115 and 125 of the first and second semiconductor chips 110 and 120 of the second sub-stack SS2 may be electrically connected to the second substrate pads 255B using vertical wires 235.

The vertical wires 235 may extend from the chip pads 115 and 125 of each of the plurality of first and second semiconductor chips 110 and 120 to the lower surface of the molding film 190, and may be connected to the first and second substrate pads. The vertical wires 235 may include or be, but are not limited to, gold (Au), silver (Ag), lead (Pb), aluminum (Al), copper (Cu), or an alloy thereof, similar to a conventional wire.

In this manner, the chip stack ST3 in the present embodiment may reduce an occupied area of the chip stack ST3 without additional space consumption due to stacking step-wise, and further, may reduce a size of the semiconductor package 200. In the present embodiment, it is illustrated that the first and second sub-stacks SS1 and SS2 are stacked in the same order of the first semiconductor chip 110 and the second semiconductor chip 120, but are not limited thereto, and at least one sub-stack may include the first and second semiconductor chips 110 and 120 stacked in a different order.

The package substrate 250 in the present embodiment may include a redistribution structure. The package substrate 250 may be disposed below the molding film 190. The package substrate 250 may include a plurality of insulating layers 251, first and second substrate pads 255A and 255B connected to vertical wires 235, redistribution layers 252 and redistribution vias 253, redistributing the first and second substrate pads 255A and 255B.

The plurality of insulating layers 251 may include an insulating resin. The insulating resin may include a thermosetting resin such as an epoxy resin, a thermoplastic resin such as a polyimide, or a resin in which an inorganic filler or/and a glass fiber are impregnated into these resins, for example, a prepreg, an Ajinomoto build-up film (ABF), a fire retardent-4 (FR-4), bismaleimide triazine (BT), or the like. According to an embodiment, the insulating layer 251 may include a photosensitive resin such as a Photo-Imageable Dielectric (PID), for example, a photosensitive polyimide, a polybenzoxazole (PBO), a phenol-based polymer, a benzocyclobutene-based polymer, or the like.

The redistribution layers 252 may be disposed below an uppermost insulating layer 251, and may include the first and second substrate pads 255A and 255B connected to the vertical wires 235 as an uppermost layer. The redistribution layers 252 may include, for example, a ground pattern, a power pattern, and a signal pattern. The signal pattern may provide a path for transmitting/receiving various signals, for example, a data signal or the like, excluding a ground signal, a power signal, or the like. The redistribution layers 252 may include more or fewer layers than those illustrated in the drawings (e.g., three layers). The redistribution vias 253 may penetrate the insulating layer 251 to connect the redistribution layers 252. The redistribution layers 252 and the redistribution vias 253 may include, for example, a metal material including copper (Cu), aluminum (Al), silver (Ag), tin (Sn), gold (Au), nickel (Ni), lead (Pb), titanium (Ti), or an alloy thereof. The redistribution vias 253 may have a structure integrated with adjacent redistribution layers 252, but are not limited thereto.

The external connection terminal 160 may be disposed below the package substrate 250, and may be connected to the redistribution layer 252. The package substrate 250 may further include an underbump metal layer between the external connection terminal 160 and the redistribution layers 252. A protective layer 261 may be disposed below the package substrate 250. The protective layer 261 may protect a lowermost redistribution layer 252 or the underbump metal layer from external physical and chemical damage. The protective layer 261 may include an insulating material, and may be formed using, for example, a photo solder resist (PSR).

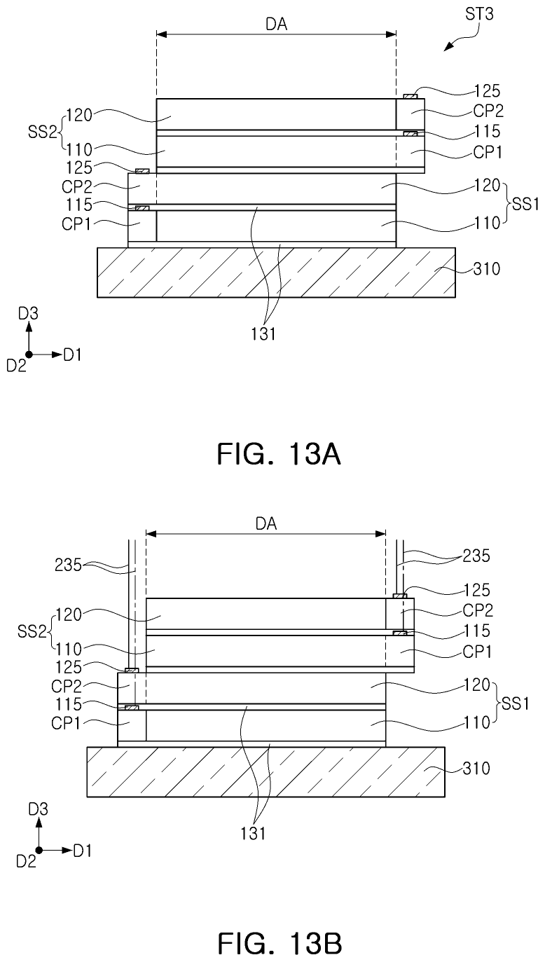

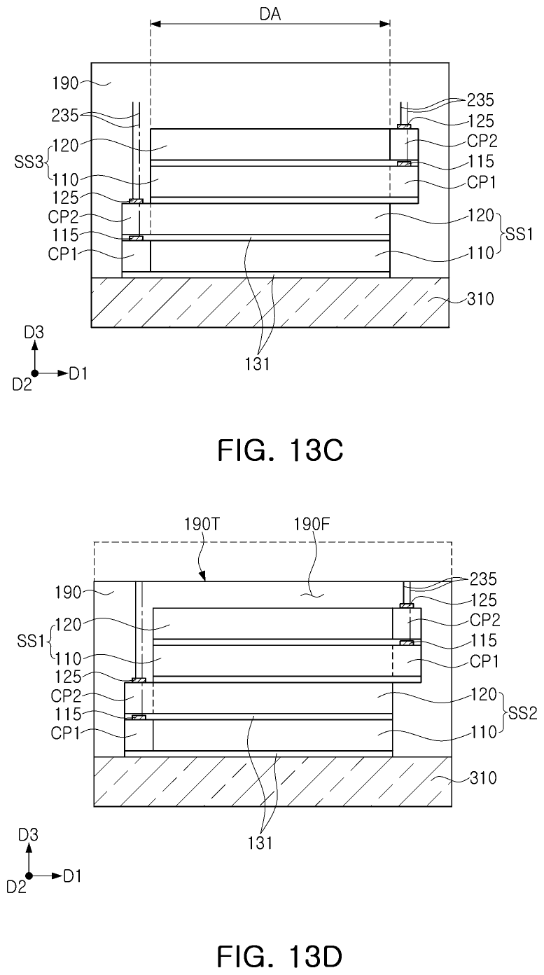

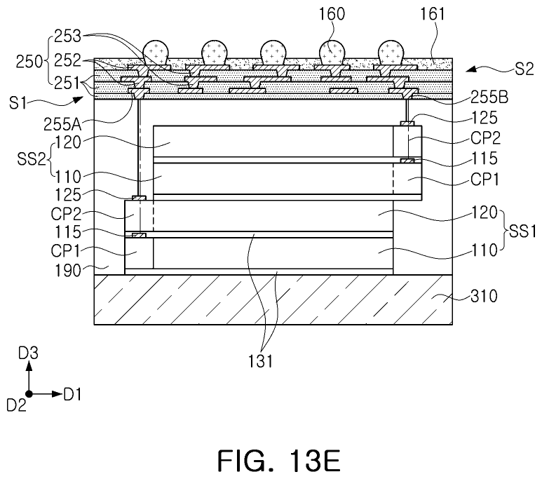

FIGS. 13A to 13E are perspective views of major processes illustrating a method for manufacturing the semiconductor package of FIG. 11.

Referring to FIG. 13A, a chip stack ST3 may be prepared by sequentially stacking first and second semiconductor chips 110 and 120 on a carrier substrate 310.

The carrier substrate 310 may be a temporary support including a glass wafer, a curable resin layer, or the like. The chip stack ST3 may be formed similarly to the chip stack ST described in FIGS. 5A and 5B, and description related thereto may be combined with description of the present embodiment. Specifically, a plurality of first and second semiconductor chips 110 and 120 may be stacked such that chip pads 115 and 125 face in an upward direction. The plurality of first and second semiconductor chips 110 and 120 may be bonded to each other by an adhesive member 131. In the chip stack ST3, even though all the first and second semiconductor chips 110 and 120 are stacked such that device regions DA almost overlap, all of the chip pads 115 and 125 of first and second chip pad regions CP1 and CP2 may be opened in an upward direction.

Next, referring to FIG. 13B, a wire 235 may be formed on the chip pads 115 and 125. Next, referring to FIG. 13C, a molding film 190 may be formed to cover the chip stack ST3 on which the wire 235 is formed.

The wire 235 may be formed on each of the chip pads 115 and 125 using a capillary of a wire bonder. The wire 235 may be formed in a nearly vertical direction (D3), and may be formed on a level, sufficiently higher than an upper surface of the chip stack ST3. After forming the wire 235, the molding film 190 may be formed on the carrier substrate 310 to cover the chip stack ST3 and the wire 235. The molding film 190 may be formed to cover at least upper surfaces of all the wires 235.

Next, referring to FIG. 13D, the molding film 190 may be ground such that an upper surface 190T of the flattened molding film 190 exposes an upper surface of the wire 235. Even after the grinding process, a molding film portion 190F may remain on the upper surface of the chip stack ST3. All of the wires 235 connected to the chip pads 115 and 125 may be disposed on the remaining molding film portion 190F. In addition, all of the wires 235 may be exposed to the upper surface 190T of the molding film 190, and an exposed surface may have an elliptical shape.

Next, referring to FIG. 13E, a package substrate 250 and external connection terminals 160, which may be redistribution structures, may be formed on the molding film 190.

The package substrate 250 may include an insulating layer 251, redistribution layers 252 having first and second substrate pads 255A and 255B, and redistribution vias 253. The insulating layer 251 may be formed by sequentially applying and curing a photosensitive material, for example, a PID. The redistribution layers 252 and redistribution vias 253 may be formed by performing an exposure process and a development process to form via holes penetrating the insulating layer 251, and patterning a metal material on the insulating layer 251 using a plating process. The package substrate 250 in the present embodiment may be formed by repeatedly performing an exposure process, a development process, a plating process, or the like. The external connection terminal 160 may be formed within an opening of the protective layer 161. For example, the external connection terminal 160 may be formed by a solder ball attachment process.

In some embodiments, after removing the carrier substrate 310, an additional molding layer may be applied on the molding film 190 from which the chip stack ST3 is exposed. The additional molding layer may be provided in advance as a preliminary molding layer on the carrier substrate, before forming the chip stack in the process of FIG. 13A.

In some embodiments, the package substrate 250 may include a package substrate 150, such as a printed circuit board, described in FIG. 1, and may be implemented by bonding the pre-fabricated package substrate 150 after the process of FIG. 13D. For example, it may be performed by bonding the first and second substrate pads 155A and 155B of the package substrate 150 to be connected to the wire 235 exposed on the upper surface 190T of the molding film 190.

The semiconductor package according to the present embodiment may be implemented with a structure including a different number of semiconductor chips. FIG. 14 is a cross-sectional side view illustrating a semiconductor package according to an embodiment, which may include a chip stack including eight semiconductor chips.

Referring to FIG. 14, a semiconductor package 200A according to the present embodiment includes chip stacks ST4 in which four first semiconductor chips 110 and four second semiconductor chips 120 are stacked, and in a similar manner to the embodiments of FIGS. 11 and 12, chip pads 115 and 125 may be configured to face an upper surface of a package substrate 250.

The chip stack ST4 in the present embodiment may include first to fourth sub-stacks SS1″, SS2″, SS3″, and SS4″ respectively including a pair of first and second semiconductor chips 110 and 120.

The first semiconductor chips 110 of the first to fourth sub-stacks SS1″, SS2″, SS3″, and SS4″ may have the same shape (structure) as each other, and the second semiconductor chips 120 of the first to fourth sub-stacks SS1″, SS2″, SS3″, and SS4″ may have the same shape (structure) as each other.

Each of the first to fourth sub-stacks SS1″, SS2″, SS3″, and SS4″ may include the first and second semiconductor chips 110 and 120 stacked such that device regions DA overlap each other, but the first and second chip pad regions CP1 and CP2 of the first and second semiconductor chips 110 and 120 may be stacked not to overlap while facing the same side of the package substrate 250.

The chip stack ST4 in the present embodiment may partially introduce a step-wise stacking method.

Specifically, the first and second chip pad regions CP1 and CP2 of the first and second sub-stacks SS1″ and SS2″ may be disposed to face a first side S1 of the package substrate 250, and the second sub-stack SS2″ may be offset-stacked on the first sub-stack SS1′ by a first distance O1′ in the positive first direction (+D1). Similarly, the first and second chip pad regions CP1 and CP2 of the third and fourth sub-stacks SS3″ and SS4″ may be disposed to face a second side S2 of the package substrate 250, and the fourth sub-stack SS4″ may be offset-stacked on the third sub-stack SS3′ by a second distance O2′ in the negative first direction (−D1).

Additionally, in the present embodiment, the third sub-stack SS3″ may also be offset-stacked with respect to a device region DA by a predetermined distance O3 from the second sub-stack SS2′.

In this manner, by appropriately stacking the first to fourth sub-stacks SS1″, SS2″, SS3″, and SS4″ with an offset, all chip pads 115 and 125 of the eight semiconductor chips 110 and 120 may be configured to be vertically connected to the first and second substrate pads 255A and 255B of the package substrate 250 by wires 235.

According to the above-described embodiments, semiconductor chips may have chip pad regions partially protruding from other regions on a first side of the device region, and may be stacked such that the chip pad regions do not overlap in a stacking direction, to minimize an area occupied by a chip stack in a semiconductor package and to reduce a size of the semiconductor package.

Various advantages and effects of the present inventive concept are not limited to the above-described contents, and will be more easily understood in the process of explaining specific embodiments.

While example embodiments have been illustrated and described above, it will be apparent to those skilled in the art that modifications and variations could be made without departing from the scope of the present inventive concept.

What is claimed is:

1. A semiconductor package comprising:
a package substrate having a first side and a second side opposing the first side, the package substrate including first substrate pads adjacent to the first side and second substrate pads adjacent to the second side; and
a chip stack including a plurality of semiconductor chips disposed between the first substrate pads and the second substrate pads on the package substrate, wherein the plurality of semiconductor chips include first to fourth semiconductor chips each having a same device region,
wherein each of the first and third semiconductor chips includes a corresponding first chip pad region protruding from a first region of a first side of the device region of the first and third semiconductor chips, each of the second and fourth semiconductor chips includes a corresponding second chip pad region protruding from a second region of a first side of the device region of the second and fourth semiconductor chips, and a plurality of chip pads disposed in each of the first and second chip pad regions, the plurality of chip pads include a first plurality of chip pads in a first chip pad region of the first and third semiconductor chips, and a second plurality of chip pads in a second chip pad region of the second and fourth semiconductor chips;
the first and second semiconductor chips are stacked such that the first chip pad region of the first semiconductor chip and the second chip pad region of the second semiconductor chip face the first side of the package substrate and do not overlap each other in a stacking direction, and the first plurality of chip pads of the first semiconductor chip and the second plurality of chip pads of the second semiconductor chip are electrically connected to the first substrate pads, and
the third and fourth semiconductor chips are stacked such that the first chip pad region of the third semiconductor chip and the second chip pad region of the fourth semiconductor chip face the second side of the package substrate and do not overlap each other in the stacking direction, and first plurality of chip pads of the third semiconductor chip and the second plurality of chip pads of the fourth semiconductor chip are electrically connected to the second substrate pads.

2. The semiconductor package of claim 1, wherein each device region of the first to fourth semiconductor chips has a rectangular shape in plan view, and
the first side of each device region of the corresponding first to fourth semiconductor chips is a long side of the rectangular shape.

3. The semiconductor package of claim 1, wherein each of the first and second chip pad regions has a protruding width, greater than a width of each chip pad of the first and second plurality of chip pads.

4. The semiconductor package of claim 1, wherein, in a first horizontal direction along the first side of the device region, a first length of the first chip pad region is equal to a second length of the second chip pad region, and a number of chip pads in the first plurality of chip pads disposed in the first chip pad region is equal to a number of chip pads in the second plurality of chip pads disposed in the second chip pad region.

5. The semiconductor package of claim 1, wherein the first and second chip pad regions facing a second horizontal direction are spaced apart from each other in a first horizontal direction along the first side of the device region.

6. The semiconductor package of claim 1, wherein the first to fourth semiconductor chips are stacked such that the plurality of chip pads face upward away from the package substrate, and each chip pad of the plurality of chip pads is connected to a corresponding substrate pad of the first and second substrate pads by a corresponding wire.

7. The semiconductor package of claim 1, wherein the first to fourth semiconductor chips are stacked such that the plurality of chip pads faces the package substrate, and each chip pad of the plurality of chip pads is connected to a corresponding substrate pad of the first and second substrate pads by a corresponding wire.

8. The semiconductor package of claim 7, wherein the first and second substrate pads are disposed at an upper surface of the package substrate in a region overlapping the first and second chip pad regions.

9. The semiconductor package of claim 7, further comprising a molding film disposed on the package substrate and surrounding the chip stack,
wherein the molding film has a portion between the chip stack and the package substrate.

10. The semiconductor package of claim 1, wherein the chip stack comprises the first semiconductor chip, the second semiconductor chip, the third semiconductor chip, and the fourth semiconductor chip stacked in that order.

11. The semiconductor package of claim 1, wherein the chip stack comprises the first semiconductor chip, the third semiconductor chip, the second semiconductor chip, and the fourth semiconductor chip stacked in that order.

12. The semiconductor package of claim 1, wherein the chip stack comprises the first semiconductor chip, the fourth semiconductor chip, the second semiconductor chip, and the third semiconductor chip stacked in that order.

13. A semiconductor package comprising:
a package substrate having a first side and a second side, opposing the first side, the package substrate including first substrate pads adjacent to the first side and second substrate pads adjacent to the second side; and
a chip stack including a plurality of sub-stacks disposed between the first substrate pads and the second substrate pads on the package substrate, and each sub-stack of the plurality of sub-stacks having a corresponding first semiconductor chip and a second semiconductor chip,
wherein each of the first semiconductor chips and the second semiconductor chips include a device region, the first semiconductor chips include corresponding first chip pad regions protruding from a first region of a first side of the device region of the first semiconductor chips, the second semiconductor chips include corresponding second chip pad regions protruding from a second region of a first side of the device region of the second semiconductor chips, and a plurality of chip pads are disposed in the first chip pad region and in the second chip pad region,
the plurality of sub-stacks include a first sub-stack and a second sub-stack, sequentially stacked on the package substrate,
in the first sub-stack, the first and second semiconductor chips are stacked such that the first and second chip pad regions face the first side of the package substrate and do not overlap each other in a stacking direction, and each chip pad of the plurality of chip pads in the first chip pad region and the second chip pad region of the first sub-stack is connected to a corresponding substrate pad of the first substrate pads by a corresponding wire,
in the second sub-stack, the first and second semiconductor chips are stacked such that the first and second chip pad regions face the second side of the package substrate and do not overlap each other in the stacking direction, and each chip pad of the plurality of chip pads in the first chip pad region and the second chip pad region of the second sub-stack is connected to a corresponding substrate pad of the second substrate pads by a corresponding wire.

14. The semiconductor package of claim 13, wherein the plurality of sub-stacks further include a third sub-stack and a fourth sub-stack,
in the third sub-stack, the first and second semiconductor chips are stacked such that the first and second chip pad regions face the first side and do not overlap each other in the stacking direction, and each chip pad of the plurality of chip pads in the first chip pad region and the second chip pad region of the third sub-stack is connected to a corresponding substrate pad of the first substrate pads by a corresponding wire, and
in the fourth sub-stack, the first and second semiconductor chips are stacked such that the first and second chip pad regions face the second side and do not overlap each other in the stacking direction, and each chip pad of the plurality of chip pads in the first chip pad region and the second chip pad region of the fourth sub-stack is connected to a corresponding substrate pad of the second substrate pads by a corresponding wire.

15. The semiconductor package of claim 14, wherein the first and second semiconductor chips are stacked such that the plurality of chip pads face upward away from the package substrate, and each chip pad of the plurality of chip pads is connected to a corresponding substrate pad of the first and second substrate pads by a corresponding wire.

16. The semiconductor package of claim 15, wherein the chip stack comprises the first sub-stack, the second sub-stack, the third sub-stack, and the fourth sub-stack sequentially stacked in that order, and
the first to fourth sub-stacks are sequentially stacked such that each of the device regions of the first and second semiconductor chips overlap in the stacking direction.

17. The semiconductor package of claim 15, wherein
the chip stack comprises the first sub-stack, the third sub-stack, the second sub-stack, and the fourth sub-stack sequentially stacked,
the third sub-stack is stacked step-wise on the first sub-stack such that the first and second chip pad regions of the first sub-stack are open,
the fourth sub-stack is stacked step-wise on the second sub-stack such that the first and second chip pad regions of the second sub-stack are open, and
the second and third sub-stacks are stacked such that each of the device regions of the first and second semiconductor chips overlap in the stacking direction.

18. The semiconductor package of claim 14, wherein the first and second semiconductor chips are stacked such that the plurality of chip pads face the package substrate, and each chip pad of the plurality of chip pads is connected to a corresponding substrate pad of the first and second substrate pads by a corresponding wire.

19. The semiconductor package of claim 18, wherein the chip stack comprises the first sub-stack, the third sub-stack, the second sub-stack, and the fourth sub-stack sequentially stacked, and
the third sub-stack is stacked step-wise on the first sub-stack such that the first and second chip pad regions of the first sub-stack are open,
the fourth sub-stack is stacked step-wise on the second sub-stack such that the first and second chip pad regions of the second sub-stack are open, and
the second and third sub-stacks are stacked such that the device regions of the first and second semiconductor chips overlap in the stacking direction.

20. A semiconductor package comprising:
a package substrate including substrate pads;
a chip stack including a plurality of semiconductor chips stacked on the package substrate; and
a molding film surrounding the chip stack on the package substrate,
wherein the plurality of semiconductor chips include first and second semiconductor chips each having a device region having the same size and the same shape,
the first and second semiconductor chips include first and second chip pad regions protruding from different regions of a first side of the device region, respectively, and a plurality of chip pads in each of the first and second chip pad regions, each chip pad of the plurality of chip pads being connected to the substrate pads by a corresponding wire, and
the first and second semiconductor chips are stacked such that the first and second chip pad regions face a first horizontal direction and do not overlap each other in a stacking direction.
